(19) United States
(12) Patent Application Publication
(10) Pub. No.: US 2017/0221986 A1
(43) Pub. Date: Aug. 3, 2017

(54) COPOLAR INTEGRATED DIODE

(71) Applicant: Jiaxing Aihe Electronics Co., Ltd., Jiaxing (CN)

(72) Inventors: Tao Wei, Jiaxing (CN); Richard Morgan Ho, Jiaxing (CN)

(21) Appl. No.: 15/211,824

(22) Filed: Jul. 15, 2016

(30) Foreign Application Priority Data
Jan. 28, 2016 (CN) 201610060179.9

(51) Int. Cl. H01L 29/06; H01L 27/08

(52) U.S. Cl. CPC H01L 29/063; H01L 27/0814; H01L 29/0649

(57) ABSTRACT

The present invention belongs to the technical field of semiconductors and discloses a copolar integrated diode, including a plurality of diode structures sharing anodes or cathodes. The copolar integrated diode comprises a semiconductor substrate; a low-doped drift region is doped on the semiconductor substrate; two or more electrodes are connected to the low-doped drift region; wherein, between the low-doped drift region and the semiconductor substrate or in the case of forming a PN junction in the low-doped drift region, the distances from the two or more electrodes to the PN junction of the diode structure are different. The present invention provides an integrated structure of a plurality of diodes, which is low in space occupancy and high in security.

### CROSS-REFERENCE TO RELATED APPLICATIONS

This application claims priority to Chinese Patent Application No. 201610060179.9, filed Jan. 28, 2016, of which the full disclosure of this application is incorporated herein by reference for all purposes.

### BACKGROUND

The present invention relates to the technical field of semiconductors, in particular to a copolar integrated diode.

A plurality of diodes with different breakdown voltages (BV) are often present in many circuit applications, and the cathodes or anodes of the diodes are connected together.

In an integrated circuit, these diodes must be carefully placed to reduce unnecessary mutual circuit induction effects, so as to prevent unnecessary breakdown, pressure breakdown or latch. A very large space generally needs to be retained between adjacent diodes, and an additional isolation layer is needed in general. The disadvantage of this solution is that a large amount of space of a semiconductor chip is occupied. In particular, with regard to the diodes with higher breakdown voltages, the situation will become more serious.

The present invention provides a copolar integrated diode, for solving the technical problem of large semiconductor chip occupancy in the prior art in the case of copolar connection of a plurality of diodes.

To solve the above technical problem, the present invention provides a copolar integrated diode, which is an integrated structure of a plurality of common-anode or common-cathode diodes; the copolar integrated diode includes a semiconductor substrate; a low-doped drift region is doped on the semiconductor substrate; two or more electrodes are connected to the low-doped drift region; and wherein, between the low-doped drift region and the semiconductor substrate or in the case of forming a PN junction in the low-doped drift region, the distances from the two or more electrodes to the PN junction of the diode structure are different. Further, the low-doped drift region is an N-type low-doped drift region;a heavily doped P-type region is arranged in the N-type low-doped drift region; the doping concentration of the heavily doped P-type region is higher than the doping concentration of the N-type low-doped drift region for at least one order of magnitude; and wherein, the heavily doped P-type region constitutes an anode to constitute two or more common-anode diodes with different breakdown voltages together with the two or more electrodes.

Further, at least two heavily doped N-type contact regions are arranged in the N-type low-doped drift region; the doping concentration of the heavily doped N-type contact regions is higher than the doping concentration of the N-type low-doped drift region for at least one order of magnitude; and wherein, the heavily doped N-type contact regions constitute a cathode; and the two or more electrodes are connected with the heavily doped N-type contact regions and constitute the two or more diodes with different breakdown voltages together with the heavily doped P-type region.

Further, insulating isolation layers are arranged between any adjacent heavily doped P-type regions and the heavily doped N-type contact regions and between any adjacent heavily doped N-type contact regions; and wherein, the insulating isolation layer is made of an insulating isolation material, and the depth of the insulating isolation layer is larger than the depths of the heavily doped P-type region and the heavily doped N-type contact region.

Further, the low-doped drift region is a P-type low-doped drift region; a heavily doped N-type region is arranged in the P-type low-doped drift region; the doping concentration of the heavily doped N-type region is higher than the doping concentration of the P-type low-doped drift region for at least one order of magnitude; and wherein, the heavily doped N-type region constitutes a cathode to constitute two or more common-cathode diodes with different breakdown voltages together with the two or more electrodes.

Further, at least two heavily doped P-type contact regions are arranged in the P-type low-doped drift region; the doping concentration of the heavily doped P-type contact regions is higher than the doping concentration of the P-type low-doped drift region for at least one order of magnitude; and wherein, the heavily doped P-type contact regions constitute the anode; and the two or more electrodes are connected with the heavily doped P-type contact regions and constitute the two or more diodes with different breakdown voltages together with the heavily doped N-type region.

Further, the insulating isolation layers are arranged between any adjacent heavily doped N-type regions and the heavily doped P-type contact regions and between any adjacent heavily doped P-type contact regions; and wherein, the insulating isolation layer is made of an insulating isolation material, and the depth of the insulating isolation layer is larger than the depths of the heavily doped N-type region and the heavily doped P-type contact region.

Further, the semiconductor substrate is P-type doped, the low-doped drift region is N-type doped, and a PN junction is formed therebetween; two or more heavily doped N-type contact regions are arranged in the low-doped drift region; and wherein, the two or more heavily doped N-type contact regions serve as the cathodes and are respectively connected with an electrode to constitute a plurality of integrated common-anode diodes together with the semiconductor substrate serving as the anode.

Further, the semiconductor substrate is N-type doped, the low-doped drift region is P-type doped, and a PN junction is formed therebetween; two or more heavily doped P-type contact regions are arranged in the low-doped drift region; and wherein, the two or more heavily doped P-type contact regions serve as the anodes and are respectively connected with an electrode to constitute a plurality of integrated common-cathode diodes together with the semiconductor substrate serving as the cathode.

Further, the insulating isolation layer is arranged between any adjacent heavily doped P-type contact regions or between any adjacent heavily doped N-type contact regions; and wherein, the insulating isolation layer is made of an insulating isolation material, and the depth of the insulating isolation layer is larger than the depth of the heavily doped P-type contact region or the heavily doped N-type contact region.

One or more technical solutions provided by the embodiments of the present application at least have the following technical effects or advantages: according to the copolar integrated diode provided by the embodiments of the present application, at least two cathodes or anodes with different distances to the PN junction are arranged in the same semiconductor chip to form an integrated structure of a plurality of common-anode or common-cathode diodes; and actually a plurality of diodes with relatively low breakdown voltages are generated in one diode with a high breakdown voltage, so the occupied space is greatly reduced.

### BRIEF DESCRIPTION OF THE DRAWINGS

Various embodiments in accordance with the present disclosure will be described with reference to the drawings, in which:

FIG. 1 is a schematic diagram of a structure of a common-anode integrated diode provided by a first embodiment of the present invention;

FIG. 2 is a schematic diagram of a structure of a common-cathode integrated diode provided by the first embodiment of the present invention;

FIG. 3 is a schematic diagram of a structure of a common-anode integrated diode provided by a second embodiment of the present invention;

FIG. 4 is a schematic diagram of a structure of a common-cathode integrated diode provided by the second embodiment of the present invention;

FIG. 5 is a schematic diagram of a structure of a common-anode integrated diode provided by a third embodiment of the present invention;

FIG. 6 is a schematic diagram of a structure of a common-cathode integrated diode provided by the third embodiment of the present invention;

FIG. 7 is a schematic diagram of a structure of a common-anode integrated diode provided by a fourth embodiment of the present invention;

FIG. 8 is a schematic diagram of a structure of a common-cathode integrated diode provided by the fourth embodiment of the present invention.

Wherein, a dotted line expresses a symbol and a connection relation of the diode.

### DETAILED DESCRIPTION

The embodiment of the present application provides a copolar integrated diode, for solving the technical problem of large semiconductor chip occupancy in the prior art in the case of copolar connection of a plurality of diodes, and realizing the technical effects of reducing the occupied space and improving the security among the diodes. To solve the above technical problem, the general idea of the technical solutions provided by the embodiment of the present application is as follows: a copolar integrated diode is an integrated structure of a plurality of common-anode or common-cathode diodes; the copolar integrated diode includes a semiconductor substrate; a low-doped drift region is doped on the semiconductor substrate; two or more electrodes are connected to the low-doped drift region; and wherein, between the low-doped drift region and the semiconductor substrate or in the case of forming a PN junction in the low-doped drift region, the distances from the two or more electrodes to the PN junction of the diode structure are different.

It can be seen from the above contents that, the integrated structure of a plurality of common-anode or common-cathode diodes is formed by forming the PN junction in the semiconductor substrate and the low-doped drift region and arranging a plurality of cathodes with different distances to the PN junction in the low-doped drift region; and actually a plurality of diodes with low breakdown voltages are formed in a diode with a high breakdown voltage, namely in the low-doped drift region of the diode constituted by one cathode farthest from the PN junction and the anode, in order to form an integrated structure of a plurality of common-anode diodes, which actually share the low-doped drift region. That is, a plurality of diodes are arranged in a diode space, so the occupied space is greatly reduced, and meanwhile the security is guaranteed.

To better understand the above technical solutions, the above technical solutions will be illustrated below in detail in combination with the attached drawings and embodiments, it should be understood that the embodiments of the present invention and the specific features in the embodiments are detailed illustrations to the technical solutions of the present application, rather than limiting the technical solutions of the present application, and the embodiments of the present application and the technical features in the embodiments can be combined with each other, as long as no conflict is generated.

Referring to FIG. 1, the copolar integrated diode provided by the present embodiment is a common-anode integrated diode, including a P-type doped semiconductor substrate P-type substrate (Anode) 101; an N-type low-doped low-doped drift region N-type drift region 102 is arranged on the semiconductor substrate P-type substrate (Anode) 101; and two or more electrodes Electrodes 105 (including a cathode Cathode 104) are connected to the low-doped drift region N-type drift region 102.

Wherein, a PN junction PN junction 103 is formed between the P-type doped semiconductor substrate P-type substrate (Anode) 101 and the N-type low-doped low-doped drift region N-type drift region 102; and the two or more electrodes Electrodes 105 (including the cathode Cathode 104) and the semiconductor substrate constitute two or more diodes with different breakdown voltages. Wherein, the electrodes Electrodes 105 include at least one or more than one electrode and one cathode Cathode 104.

The PN junction PN junction 103 is formed between the P-type doped semiconductor substrate P-type substrate (Anode) 101 and the N-type low-doped low-doped drift region N-type drift region 102, so the P-type doped semiconductor substrate P-type substrate (Anode) 101 and the N-type low-doped low-doped drift region N-type drift region 102 can constitute the anode and the cathode on an electrical structure, and are connected with the electrodes Electrodes 105 and the cathode Cathode 104 to constitute a complete diode structure.

A plurality of electrodes Electrodes 105 and the cathode Cathode 104 with different distances to the PN junction PN junction 103 are connected to the low-doped drift region N-type drift region 102 to form a plurality of diodes with different breakdown voltages BV on the electrical structure in the N-type low-doped drift region N-type drift region 102.

A dotted line connecting structure in FIG. 1 expresses the connection relation of a plurality of different diodes, specifically, a diode Diode 106 is the diode structure formed by the cathode Cathode 104 and the anode, namely the P-type doped semiconductor substrate P-type substrate (Anode) 101, and a dotted line expresses an electrical connection relation; the diodes with different breakdown voltages are formed according to the distances from the electrodes Electrodes 105 and the cathode Cathode 104 to the PN junction PN junction 103, and the substrate is shared; and thus, the occupied space of the formed integrated structure is greatly reduced.

The positions of the electrodes Electrodes 105 (including the cathode Cathode 104) and the distances therefrom to the PN junction determine the BV of a single diode. The BV of the single diode can be generally determined by an experiment or simulating calculation.

Meanwhile, a common-cathode integrated diode can also be formed by inverting the doping attributes.

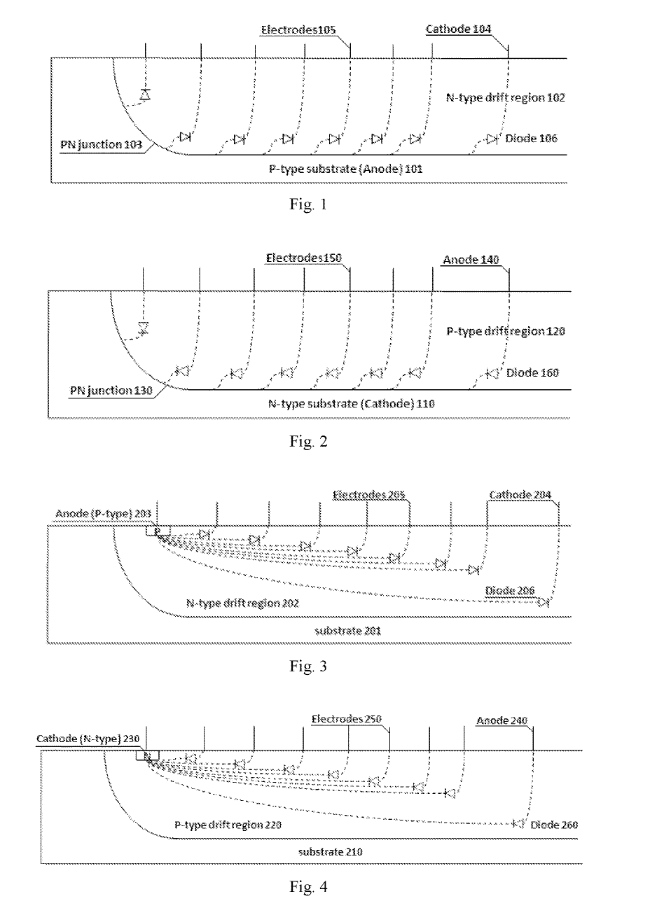

Referring to FIG. 2, it shows another structure of the copolar integrated diode provided by the present embodiment is a common-cathode integrated diode, including an N-type doped semiconductor substrate N-type substrate (Anode) 110; a P-type low-doped low-doped drift region P-type drift region 120 is arranged on the semiconductor substrate N-type substrate (Cathode) 110; and two or more electrodes Electrodes 150 (including an anode Anode 140) are connected to the low-doped drift region P-type drift region 120.

Wherein, a PN junction PN junction 130 is formed between the N-type doped semiconductor substrate N-type substrate (Cathode) 110 and the P-type low-doped low-doped drift region P-type drift region 120; and the two or more electrodes Electrodes 150 (including the anode Anode 140) and the semiconductor substrate constitute two or more diodes with different breakdown voltages. Wherein, the electrodes Electrodes 150 include at least one electrode and one anode Anode 140.

The PN junction PN junction 130 is formed between the N-type doped semiconductor substrate N-type substrate (Cathode) 110 and the P-type low-doped low-doped drift region P-type drift region 120, so the N-type doped semiconductor substrate N-type substrate (Cathode) 110 and the P-type low-doped low-doped drift region P-type drift region 120 can constitute the cathode and the anode on the electrical structure, and are connected with the electrodes Electrodes 150 and the anode Anode 140 to constitute a complete diode structure.

A plurality of electrodes Electrodes 150 and the anode Anode 140 with different distances to the PN junction PN junction 130 are connected to the low-doped drift region P-type drift region 120 to form a plurality of diodes with different breakdown voltages BV on the electrical structure in the P-type low-doped low-doped drift region P-type drift region 120.

A dotted line connecting structure in FIG. 2 expresses the connection relation of a plurality of different diodes, specifically, a diode Diode 160 is the diode structure formed by the anode Anode 140 and the cathode, namely the N-type doped semiconductor substrate N-type substrate (Cathode) 110, and a dotted line expresses an electrical connection relation; the diodes with different breakdown voltages are formed according to the distances from the electrodes Electrodes 150 and the anode Anode 140 to the PN junction PN junction 130, and the substrate is shared; and thus, the occupied space of the formed integrated structure is greatly reduced.

The positions of the electrodes Electrodes 150 and the distances therefrom to the PN junction determine the BV of a single diode. The BV of the single diode can be generally determined by an experiment or simulating calculation.

Referring to FIG. 3 and FIG. 4, on the basis of the above embodiment 1, the copolar integrated diode provided by the present embodiment is provided with an independent heavily doped P-type region for the common-anode integrated diode to constitute a P-type heavily doped anode Anode (P-type) 205, in order to replace the anode function of the substrate. Or, an independent heavily doped N-type region is arranged for the common-cathode integrated diode to constitute an N-type heavily doped cathode Cathode (N-type) 240, in order to replace the cathode function of the substrate.

Referring to FIG. 3, the copolar integrated diode provided by the present embodiment is a common-anode integrated diode, including a semiconductor substrate substrate 201 and an N-type low-doped drift region N-type drift region 202 arranged therein; a heavily doped P-type region is arranged in the N-type low-doped drift region to constitute a P-type heavily doped anode Anode (P-type) 203; and two or more electrodes Electrodes 205 (including a cathode Cathode 204) are connected to the low-doped drift region N-type drift region 202.

Wherein, a PN junction is formed between the N-type low-doped low-doped drift region N-type drift region 202 and the P-type heavily doped anode Anode (P-type) 203; and the two or more electrodes Electrodes 205 and the cathode Cathode 204 constitute two or more diodes with different breakdown voltages together with the anode Anode (P-type) 203.

The doping concentration of the heavily doped P-type region is higher than the doping concentration of the N-type low-doped drift region for at least one order of magnitude.

Wherein, the P-type heavily doped anode Anode (P-type) 203 constitutes the anode of the common-anode integrated diode; and the two or more electrodes Electrodes 205 (including the cathode Cathode 204) constitute the cathode of the common-anode integrated diode and constitute the two or more diodes with different breakdown voltages together with the anode Anode (P-type) 203.

The semiconductor substrate substrate 201 can be intrinsic, P-type doped or N-type doped; the PN junction is formed between the anode Anode (P-type) 203 and the N-type low-doped drift region N-type drift region 202, so the anode Anode (P-type) 203 and the N-type low-doped drift region N-type drift region 202 can constitute the anode and the cathode on an electrical structure, and the electrodes Electrodes 205 and the cathode Cathode 204 are connected to the N-type low-doped drift region N-type drift region 202 to constitute a complete structure with a plurality of diodes.

A dotted line connecting structure in FIG. 3 expresses the formed plurality of different diodes, a diode Diode 206 is the diode structure formed by the cathode Cathode 204 and the anode Anode (P-type) 203, and a dotted line expresses an electrical connection relation; the diodes with different breakdown voltages are formed according to the distances from the electrodes Electrodes 205 and the cathode Cathode 204 to the PN junction; and the anode shares the P-type heavily doped Anode (P-type) 203, so a plurality of common-anode diodes with smaller breakdown voltages are constituted between the cathode Cathode 204 farthest from the PN junction and the P-type heavily doped Anode (P-type) 203, and the space occupied by the formed integrated structure is greatly reduced.

The positions of the electrodes Electrodes 205 and the cathode Cathode 204 and the distances therefrom to the left-end PN junction determine the BV of a single diode. The BV of the single diode can be generally determined by an experiment or simulating calculation.

Meanwhile, the present embodiment also provides a common-cathode integrated diode by inverting the doping attributes.

Referring to FIG. 4, the copolar integrated diode provided by the present embodiment is a common-cathode integrated diode, including a semiconductor substrate substrate 210 and a P-type low-doped low-doped drift region P-type drift region 220 arranged therein; a heavily doped N-type region is arranged in the P-type low-doped drift region to constitute an N-type heavily doped cathode Cathode (N-type) 230; and two or more electrodes Electrodes 250 (including an anode Anode 240) are connected to the low-doped drift region P-type drift region 220.

Wherein, a PN junction is formed between the P-type low-doped drift region P-type drift region 220 and the N-type heavily doped cathode Cathode (N-type) 230; and the two or more electrodes Electrodes 250 (including the anode Anode 240) and the cathode Cathode (N-type) 230 constitute two or more diodes with different breakdown voltages.

The doping concentration of the heavily doped N-type region is higher than the doping concentration of the P-type low-doped drift region for at least one order of magnitude.

Wherein, the N-type heavily doped cathode Cathode (N-type) 230 constitutes the cathode of the common-cathode integrated diode; and the two or more electrodes Electrodes 250 (including the anode Anode 240) constitute the anode of the common-cathode integrated diode and constitute the two or more diodes with different breakdown voltages together with the cathode Cathode (N-type) 230.

The semiconductor substrate substrate 210 can be intrinsic, P-type doped or N-type doped; the PN junction is formed between the cathode Cathode (N-type) 230 and the P-type low-doped drift region P-type drift region 220, so the cathode Cathode (N-type) 230 and the P-type low-doped drift region P-type drift region 220 can constitute the cathode and the anode on an electrical structure, and the electrodes Electrodes 250 and the anode Anode 240 are connected to the P-type low-doped drift region P-type drift region 220 to constitute a complete structure with a plurality of diodes.

A dotted line connecting structure in FIG. 4 expresses the formed plurality of different diodes, a diode Diode 260 is the diode structure formed by the anode Anode 240 and the cathode Cathode (N-type) 230, and a dotted line expresses an electrical connection relation; the diodes with different breakdown voltages are formed according to the distances from the electrodes Electrodes 250 and the anode Anode 240 to the PN junction; and the cathode shares the N-type heavily doped cathode Cathode (N-type) 230, so a plurality of common-cathode diodes with smaller breakdown voltages are constituted between the anode Anode 240 farthest from the PN junction and the N-type heavily doped cathode Cathode (N-type) 230, and the space occupied by the formed integrated structure is greatly reduced.

The positions of the electrodes Electrodes 250 and the anode Anode 240 and the distances therefrom to the left-end PN junction determine the BV of a single diode. The BV of the single diode can be generally determined by an experiment or simulating calculation.

Referring to FIG. 5, the copolar integrated diode provided by the present embodiment is a common-anode integrated diode, including a semiconductor substrate substrate 301; an N-type low-doped drift region N-type drift region 302 is doped on the semiconductor substrate substrate 301; and a heavily doped P-type region is arranged in the N-type low-doped drift region N-type drift region 302 to constitute a P-type heavily doped anode Anode (P⁺) 303.

At least two heavily doped N-type contact regions N⁺ Cathodes 305 and N⁺ Cathode 304 are arranged in the N-type low-doped drift region N-type drift region 302.

The doping concentration of the heavily doped P-type region is higher than the doping concentration of the N-type low-doped drift region N-type drift region 302 for at least one order of magnitude; and the doping concentration of the heavily doped N-type contact regions N⁺ Cathodes 305 and N⁺ Cathode 304 is higher than the doping concentration of the N-type low-doped drift region N-type drift region 302 for at least one order of magnitude.

Wherein, the P-type heavily doped anode Anode (P⁺) 303 constitutes the anode of the common-anode integrated diode; and the two or more heavily doped N-type contact regions N⁺ Cathodes 305 (including the N⁺ Cathode 304) constitute the cathode of the common-anode integrated diode and constitute two or more diodes with different breakdown voltages together with the anode Anode (P⁺) 303.

The semiconductor substrate substrate 301 can be intrinsic, P-type doped or N-type doped; the PN junction is formed between the P-type heavily doped anode Anode (P⁺) 303 and the heavily doped N-type contact regions N⁺ Cathodes 305 and N⁺ Cathode 304, so the anode Anode (P⁺) 303 and the heavily doped N-type contact regions N⁺ Cathodes 305 (including the N⁺ Cathode 304) can constitute the anode and the cathode on an electrical structure, and an electrode is connected to the heavily doped N-type contact regions N⁺ Cathodes 305 and N⁺ Cathode 304 to constitute a complete diode structure.

The diodes with different breakdown voltages are formed according to the distance from the electrode to the PN junction; the anode thereof shares the anode Anode (P⁺) 303; actually, a plurality of cathodes are arranged in the drift region in a diode space formed by the anode Anode (P⁺) 303 and the cathode N⁺ Cathode 304, and the distances to the PN junction are different, so an integrated structure of a plurality of common-anode diodes with different breakdown voltages is formed, and meanwhile, the space occupied by the formed integrated structure is greatly reduced.

The distance to the PN junction determines the BV of a single diode, and the BV of the single diode can be generally determined by an experiment or simulating calculation.

To avoid mutual interference, insulating isolation layers Field Insulations 306 are arranged between any adjacent heavily doped P-type regions and the heavily doped N-type contact regions and between any adjacent heavily doped N-type contact regions.

The insulating isolation layer Field Insulation 306 is made of an insulating isolation material, and the depth of the insulating isolation layer is larger than the depth of the heavily doped P-type region or the heavily doped N-type contact region.

In most circuit applications, high current injection and low contact resistance are necessary in general. The heavily doped N-type contact region is introduced in the present embodiment, and the doping concentration of the heavily doped N-type region is higher than the doping concentration of the drift region for at least one order of magnitude; and in addition, the isolation oxide layer Field Insulation 306 is introduced, and the depth of the isolation oxide layer is larger than that of the heavily doped N-type contact region, so the electric field balance of the drift region can be protected. The heavily doped N-type contact region provides a high injection source for the N-type low-doped drift region, and the contact resistance of the electrode is reduced. Since the N-type contact region is thinner than the isolation oxide layer Field Insulation 306, the electron depletion layer of the N-type low-doped drift region will not be influenced in the case of an external voltage, the electric field balance is retained, and the breakdown voltage will not be influenced.

Meanwhile, the present embodiment also provides a common-cathode integrated diode by inverting the doping attributes.

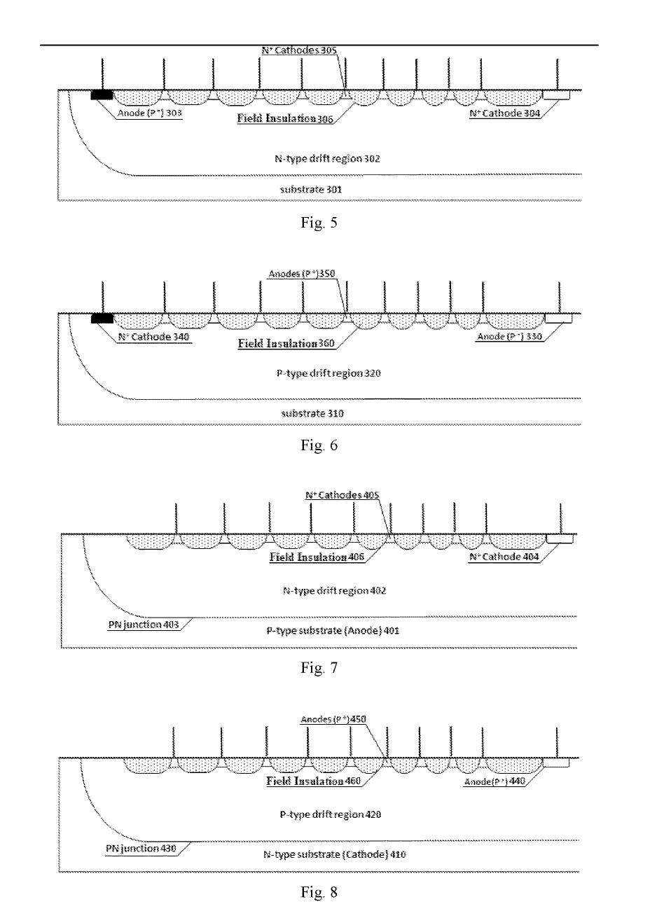

Referring to FIG. 6, the copolar integrated diode provided by the present embodiment is a common-cathode integrated diode, including a semiconductor substrate substrate 310; a P-type low-doped drift region P-type drift region 320 is doped on the semiconductor substrate substrate 310; and a heavily doped N-type region is arranged in the P-type low-doped drift region P-type drift region 320 to constitute an N-type heavily doped cathode N⁺ Cathode 340.

At least two heavily doped P-type contact regions Anodes (P⁺) 350 (including an Anode (P⁺) 330) are arranged in the P-type low-doped drift region P-type drift region 320.

The doping concentration of the heavily doped P-type contact regions Anodes (P⁺) 350 (including the Anode (P⁺) 330) is higher than the doping concentration of the P-type low-doped drift region P-type drift region 320 for at least one order of magnitude; and the doping concentration of the heavily doped N-type cathode N⁺ Cathode 340 is higher than the doping concentration of the P-type low-doped drift region P-type drift region 320 for at least one order of magnitude.

Wherein, the heavily doped N-type cathode N⁺ Cathode 340 constitutes the cathode of the common-cathode integrated diode and constitutes two or more diodes with different breakdown voltages together with the heavily doped P-type contact regions Anodes (P⁺) 350 (including the Anode (P⁺) 330) serving as the anodes.

The semiconductor substrate substrate 310 can be intrinsic, P-type doped or N-type doped; the PN junction is formed between the N-type heavily doped cathode N⁺ Cathode 340 and the heavily doped P-type contact regions Anodes (P+) 350, so the P-type contact regions Anodes (P+) 350 and the heavily doped N-type contact regions N⁺ Cathodes 340 can constitute the anode and the cathode on an electrical structure, and an electrode is connected to the heavily doped P-type contact regions Anodes (P+) 350 and the Anode (P⁺) 330 to constitute a complete diode structure.

The diodes with different breakdown voltages are formed according to the distance from the electrode to the PN junction; the cathode thereof shares the cathode N⁺ Cathode 340; actually, a plurality of cathodes are arranged in the drift region in a diode space formed by the anode Anode (P⁺) 330 and the cathode N⁺ Cathode 340, and the distances to the PN junction are different, so an integrated structure of a plurality of common-anode diodes with different breakdown voltages is formed, and meanwhile, the space occupied by the formed integrated structure is greatly reduced.

The distance to the PN junction determines the BV of a single diode, and the BV of the single diode can be generally determined by an experiment or simulating calculation.

To avoid mutual interference, insulating isolation layers Field Insulations 360 are arranged between any adjacent heavily doped P-type regions and the heavily doped N-type contact regions and between any adjacent heavily doped N-type contact regions.

The insulating isolation layer Field Insulation 360 is made of an insulating isolation material, and the depth of the insulating isolation layer is larger than the depth of the heavily doped P-type region or the heavily doped N-type contact region.

In most circuit applications, high current injection and low contact resistance are necessary in general. The heavily doped P-type contact region is introduced in the embodiment, and the doping concentration of the heavily doped P-type region is higher than the doping concentration of the drift region for at least one order of magnitude; and in addition, the isolation oxide layer Field Insulation 360 is introduced, and the depth of the isolation oxide layer is larger than that of the heavily doped P-type contact region, so the electric field balance of the drift region can be protected. The heavily doped P-type contact region provides a high injection source for the P-type low-doped drift region, and the contact resistance of the electrode is reduced. Since the P-type contact region is thinner than the isolation oxide layer Field Insulation 360, the electron depletion layer of the P-type low-doped drift region will not be influenced in the case of an external voltage, the electric field balance is retained, and the breakdown voltage will not be influenced.

Referring to FIG. 7, the copolar integrated diode provided by the present embodiment is a common-anode integrated diode, including a P-type doped semiconductor substrate P-type substrate (Anode) 401 and an N-type low-doped drift region N-type drift region 402 doped therein, and a PN junction PN junction 403 is formed therebetween; and two or more heavily doped N-type contact regions N⁺ Cathodes 405 (including an N⁺ Cathode 404) are arranged in the N-type low-doped drift region N-type drift region 402.

Wherein, the two or more heavily doped N-type contact regions serve as cathodes and are respectively connected with an electrode to constitute a plurality of integrated common-anode diodes together with the semiconductor substrate P-type substrate (Anode) 401 serving as the anode.

Further, the present embodiment also provides a common-cathode integrated diode by inverting the doping attributes.

Referring to FIG. 8, the common-cathode integrated diode includes: an N-type doped semiconductor substrate N-type substrate (Cathode) 410 and a P-type low-doped drift region P-type drift region 420 doped therein, and a PN junction PN junction 430 is formed therebetween; two or more heavily doped P-type contact regions Anodes (P+) 450 (including an Anode (P+) 440) are arranged in the P-type low-doped drift region P-type drift region 420; and wherein, the two or more heavily doped P-type contact regions serve as anodes and are respectively connected with one electrode to constitute a plurality of integrated common-cathode diodes together with the semiconductor substrate N-type substrate (Cathode) 410 serving as the cathode.

Insulating isolation layers are arranged between any adjacent heavily doped P-type contact regions and any adjacent heavily doped N-type contact regions; and wherein, the insulating isolation layer is made of an insulating isolation material, and the depth of the insulating isolation layer is larger than the depth of the heavily doped P-type region or the heavily doped N-type contact region.

One or more technical solutions provided by the embodiments of the present application at least have the following technical effects or advantages. Aaccording to the copolar integrated diode provided by the embodiments of the present application, at least two cathodes with different distances to the PN junction are arranged in the same semiconductor chip to form an integrated structure of a plurality of common-anode diodes; and actually a plurality of diodes with relatively low breakdown voltages are generated in one diode with a high breakdown voltage, so the occupied space is greatly reduced.

According to the copolar integrated diode provided by the embodiments of the present application, the high injection source is provided by the heavily doped contact region, and the contact resistance of the electrode is reduced; and the insulating isolation layer is added to prevent the breakdown voltage from being influenced by the heavily doped contact region.

Finally, it should be noted that the above-mentioned implementations are merely used for illustrating the technical solutions of the present invention, rather than limiting them; although the present invention has been described in detail with reference to the examples, those of ordinary skill in the art should understand that modifications or equivalent substitutions can be made to the technical solutions of the present invention without departing from the spirit or scope of the technical solutions of the present invention, and the modifications or equivalent substitutions shall fall within the scope of the claims of the present invention.

1. A copolar integrated diode, which is an integrated structure of a plurality of common-anode diodes or a plurality of common-cathode diodes;
wherein the copolar integrated diode comprises a semiconductor substrate;
a low-doped drift region is doped on the semiconductor substrate;
two or more electrodes are connected to the low-doped drift region;
wherein a PN junction is formed between the low-doped drift region and the semiconductor substrate, and wherein distances from the two or more electrodes to the PN junction are different for each of the two or more electrodes; and
wherein the semiconductor substrate is one of:
an anode and the two or more electrodes are cathodes to constitute two or more common-anode diodes with different breakdown voltages; or
a cathode and the two or more electrodes are anodes to constitute two or more common-cathode diodes with different breakdown voltages.

2. The copolar integrated diode of claim 1, wherein the low-doped drift region is an N-type low-doped drift region;
a heavily doped P-type region is arranged in the N-type low-doped drift region;
a doping concentration of the heavily doped P-type region is higher than a doping concentration of the N-type low-doped drift region by at least one order of magnitude; and
wherein the heavily doped P-type region constitutes the anode and the two or more electrodes are the cathodes of the two or more common-anode diodes with different breakdown voltages.

3. The copolar integrated diode of claim 2, wherein at least two heavily doped N-type contact regions are arranged in the N-type low-doped drift region;
a doping concentration of the at least two heavily doped N-type contact regions is higher than the doping concentration of the N-type low-doped drift region by at least one order of magnitude; and
wherein, the at least two heavily doped N-type contact regions constitute the cathodes, and the two or more electrodes are connected with the at least two heavily doped N-type contact regions and constitute the two or more common-anode diodes with different breakdown voltages together with the heavily doped P-type region as the anode, the anode being a common anode for the two or more common-anode diodes.

4. The copolar integrated diode of claim 3, wherein insulating isolation layers are arranged between any adjacent heavily doped P-type regions and the at least two heavily doped N-type contact regions and between any adjacent heavily doped N-type contact regions; and
wherein, the insulating isolation layers are made of an insulating isolation material, and a depth of the insulating isolation layers is larger than depths of the heavily doped P-type region and the at least two heavily doped N-type contact regions.

5. The copolar integrated diode of claim 1, wherein the low-doped drift region is a P-type low-doped drift region;
a heavily doped N-type region is arranged in the P-type low-doped drift region;
a doping concentration of the heavily doped N-type region is higher than a doping concentration of the P-type low-doped drift region for at least one order of magnitude; and
wherein the heavily doped N-type region constitutes the cathode and the two or more electrodes are the anodes of the two or more common-cathode diodes with different breakdown voltages.

6. The copolar integrated diode of claim 5, wherein at least two heavily doped P-type contact regions are arranged in the P-type low-doped drift region;
a doping concentration of the at least two heavily doped P-type contact regions is higher than the doping concentration of the P-type low-doped drift region for at least one order of magnitude; and
wherein the at least two heavily doped P-type contact regions constitute the anodes and the two or more electrodes are connected with the at least two heavily doped P-type contact regions and constitute the two or more common-cathode diodes with different breakdown voltages together with the heavily doped N-type region as the cathode, the cathode being a common cathode for the two or more common-cathode diodes.

7. The copolar integrated diode of claim 6, wherein insulating isolation layers are arranged between any adjacent heavily doped N-type regions and the at least two heavily doped P-type contact regions and between any adjacent heavily doped P-type contact regions; and
wherein, the insulating isolation layers are made of an insulating isolation material, and a depth of the insulating isolation layers is larger than depths of the heavily doped N-type region and the at least two heavily doped P-type contact regions.

8. The copolar integrated diode of claim 1, wherein the semiconductor substrate is P-type doped, the low-doped drift region is N-type doped, and the PN junction is formed therebetween;
two or more heavily doped N-type contact regions are arranged in the low-doped drift region; and
wherein, the two or more heavily doped N-type contact regions serve as the cathodes and are respectively connected with the two or more electrodes to constitute a plurality of integrated common-anode diodes together with the semiconductor substrate serving as the anode.

9. The copolar integrated diode of claim 1, wherein the semiconductor substrate is N-type doped, the low-doped drift region is P-type doped, and the PN junction is formed therebetween;
two or more heavily doped P-type contact regions are arranged in the low-doped drift region; and
wherein the two or more heavily doped P-type contact regions serve as the anodes and are respectively connected with the two or more electrodes to constitute a plurality of integrated common-cathode diodes together with the semiconductor substrate serving as the cathode.

10. The copolar integrated diode of claim 8, wherein an insulating isolation layer is arranged between any adjacent heavily doped N-type contact regions of the two or more heavily doped N-type contact regions; and
wherein, the insulating isolation layer is made of an insulating isolation material, and a depth of the insulating isolation layer is larger than a depth of the at least two heavily doped N-type contact regions.

11. The copolar integrated diode of claim 9, wherein an insulating isolation layer is arranged between any adjacent heavily doped P-type contact regions of the two or more heavily doped P-type contact regions; and
wherein, the insulating isolation layer is made of an insulating isolation material, and a depth of the insulating isolation layer is larger than a depth of the at least two heavily doped P-type contact regions.
